(19) United States
(12) Patent Application Publication
(10) Pub. No.: US 2013/0168275 A1
(43) Pub. Date: Jul. 4, 2013

(54) ELECTRONIC TABLET TRANSPORT AND RETAINING APPARATUS

(71) Applicant: James R. Hennessey, West Hartford, CT (US)

(72) Inventor: James R. Hennessey, West Hartford, CT (US)

(21) Appl. No.: 13/342,424

(22) Filed: Jan. 3, 2012

(51) Int. Cl. B65D 85/00; H05K 7/00

(52) U.S. Cl. 206/320; 248/309.1; 248/316.1; 248/288.31

(57) ABSTRACT

A case for retaining and transporting an electronic tablet includes means for coupling the case to a swivel of a mounting system. The case also includes a tablet retaining portion and a flap movable between an open position wherein the display screen is viewable and a closed position wherein a portion of the flap covers the display. The means for coupling the case to the swivel include a reinforcing plate forming part of, or retained by, the tablet retaining portion of the case. In addition, the means for coupling the swivel to the case can include a threaded aperture defined by the reinforcing plate or a member attached to the reinforcing plate. The threaded aperture is configured to threadably receive a threaded stud forming part of the swivel.

### TECHNICAL FIELD

The present invention is directed in general to electronic tablet cases and equipment and, more particularly, to a case for transporting an electronic tablet and a system and apparatus for mounting such a case for an electronic tablet on which video, text, or user-selectable applications may be displayed.

### BACKGROUND

Electronic tablets are devices that allow users to access and process information in a manner similar to that done with laptops and larger computers, but with an increased amount of portability. In particular, the smaller size and lighter weight of an electronic tablet as compared to a laptop allows it to be carried and used in various environments for reading, typing, and organizing data without being cumbersome. Furthermore, the sizes and weights of electronic tablets allow batteries used to power such tablets to have extended lives as compared to the batteries used to power standard laptops.

Electronic tablets can be used in a variety of applications including the display of music, the display of reading material or video, the display of notes in lecturing or public speaking, and for user-defined applications such as interfacing with other devices, for example, to control and/or monitor the operation of audio and visual effects. In doing so, an electronic tablet can be held by a user but is more often placed on a flat surface or strapped using elastic or hook and loop material into a usable position. This can result in an inability to ideally position the tablet or to adequately retain it so as to minimize damage.

### SUMMARY

In one aspect, the present invention resides in a case for retaining and transporting an electronic tablet. The case includes means for coupling the case to a swivel of a mounting system. In an embodiment of the present invention, the case includes a tablet retaining portion and a flap movable between an open position wherein the display screen is viewable and a closed position wherein a portion of the flap covers the tablet display.

In one embodiment, the tablet retaining portion of the case includes the means for coupling the case to the swivel. These means include a reinforcing plate forming part of, or retained by, the tablet retaining portion of the case. In addition, the means for coupling the swivel to the case can include a threaded aperture defined by the reinforcing plate or a member attached to the reinforcing plate. The threaded aperture is configured to threadably receive a threaded stud forming part of the swivel. While a threaded stud and aperture have been described, the present invention is not limited in this regard as other coupling mechanisms, such as, but not limited to, ball detents, quarter turn fasteners, bayonet fasteners, and other coupling mechanisms known to those skilled in the pertinent art which the present invention pertains may be employed.

In another aspect, the present invention resides in a system for mounting an electronic tablet such as, but not limited to, an iPad®. Such a system comprises a mounting bar configured to be coupled to a support and a swivel coupled to the mounting bar, the swivel being configured to be removably coupled to a mounting mechanism of a case or other apparatus for retaining and transporting the tablet. In operation, the above-described system can be mounted on such things as a microphone stand, sheet music stand, conductor stand, drum hardware or other music-related equipment, shopping carts, wheelchairs, baby strollers, head rests in cars, exercise equipment, desks, workstations, teleprompters, pulpits, lecterns, and the like. However, the present invention is not limited in this regard, as the above-described system may be used to mount a tablet to other surfaces or objects known to those skilled in the art to which the present invention pertains.

In another aspect, the present invention resides in a kit for mounting the case for the electronic tablet to a support. Such a kit comprises the mounting bar configured to be coupled to the support, and the swivel coupled to the mounting bar and configured to be removably coupled to the support. The electronic tablet is configured to be coupled to the attachment mechanism.

### BRIEF DESCRIPTION OF THE DRAWINGS

FIG. 1 is an exploded perspective view of a system for mounting a case for transporting an electronic tablet, in accordance with the present invention.

FIG. 2 is a perspective view of a mounting bar of the system of FIG. 1.

FIG. 3 is a side view of the mounting bar.

FIG. 4 is a top view of the mounting bar.

FIG. 5 is a side view of an attachment mechanism of the system of FIG. 1.

FIG. 6 is a perspective view of a case for transporting an electronic tablet, the case having a receiving plate of the system of FIG. 1.

FIG. 7 is a perspective view of a case for holding an electronic tablet in the system of FIG. 1.

FIG. 8 is a perspective view of an alternate embodiment of a case for holding an electronic tablet in the system of FIG. 1.

FIG. 9 is an exploded perspective view of an alternate embodiment of a system for mounting an electronic tablet.

### DETAILED DESCRIPTION

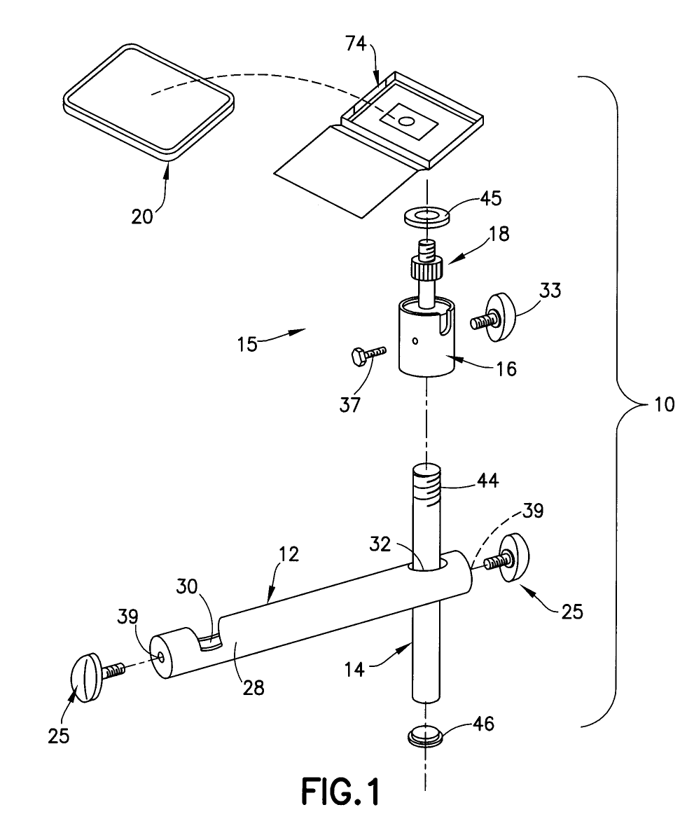

As shown in FIG. 1, a system for mounting a case for transporting an electronic tablet is designated generally by the reference number 10 and is hereinafter referred to as “system 10.” System 10 comprises a mounting bar 12, a mounting post 14 configured to be coupled to the mounting bar 12, and a swivel generally designated by the reference number 15. The swivel 15 includes a socket 16 having a ball and threaded stud 18 rotatably retained therein. In the illustrated embodiment, a case 74 having a receiving plate 22 is mountable on the threaded stud 18. The receiving plate 22 defines a threaded aperture 23 extending therethrough and configured to threadably receive the threaded stud 18. A washer 45 is received over the upper end of the threaded stud 18 to provide support for the case 74 in the mounted position on the threaded stud 18. The electronic tablet (shown at 20) is positionable in the case 74 using any suitable means. The mounting bar 12, mounting post 14, and swivel 15 can be readily assembled and disassembled, thereby defining system 10 as a kit. The kit may also include the electronic tablet. The present invention is limited to the stud 18 being threaded, however, as the stud 18 may include suitable structure such as, but not limited to, ball detents, quarter turn fasteners, bayonet-type couplings, and the like that enable the case 74 to be connected to the swivel 15.

The mounting bar 12 includes a body portion 28 defining a slot 30 adjacent one end of the body portion. The body portion 28 may also define a through hole 32 adjacent an opposing end of the body portion. The present invention is not limited in this regard, however, as slots 30 (or through holes 32) can be located proximate both ends. By coupling the mounting bar 12 to the tubing, rods, or bars of an existing support (e.g., a legged stand or base, a desk, exercise equipment, tray table, or the like) inserted into the slot 30, securing the mounting post 14 in the through hole 32 in the mounting bar 12, and coupling the electronic tablet 20 to the swivel 15 on the mounting post 14, the system 10 can be secured in place to support the electronic tablet 20. The mounting bar 12 is coupled to the support and the mounting post 14 is secured in the through hole 32 via threaded knobs 25 threadably engaged in threaded holes 39. By turning the threaded knobs 25, the tips defined by shaft portions of the knobs will engage the mounting post 14 and the tubing, rods, or bars of the existing support, thereby securing the mounting bar 12 to the existing support and securing the mounting post 14 in the through hole 32. Slots 30, however, provide for simpler mounting as compared to through holes 32 because coupling the mounting bar 12 to the existing support can be effected without removing devices (such as microphones) to allow the existing support to be inserted through the through hole 32.

The present invention is not limited to the use of the threaded knob 25, however, as other mechanisms such as toggle or spring loaded handles can also be employed without departing from the broader aspects of the present invention.

The mounting post 14 is defined by tubing sized and configured to be received in the through hole 32 of the mounting bar 12. More specifically, the mounting post 14 is of a diameter and length that allows it to be positioned in the through hole 32 at any point along the length of the mounting post and secured in the through hole via the threaded knob 25 or other clamping mechanism.

Still referring to FIG. 1, a thread 44 is formed on an upper end of the mounting post 14 to allow the mounting post to be threadedly received in the socket 16. The present invention is not so limited, however, as the socket 16 may be coupled to the mounting post 14 via any other suitable means. For example, the socket may be frictionally fit over the upper end of the mounting post, or the socket may be loosely fit over the upper end of the mounting post and clamped or otherwise non-rotatably fastened to the mounting post. A ball detent or quick release coupling may also be used. In the illustrated embodiment, the mounting post is a hollow tube having a cap 46 inserted into an end thereof. However, the present invention is not limited in this regard as the mounting post can also be solid, thereby obviating the need for a cap.

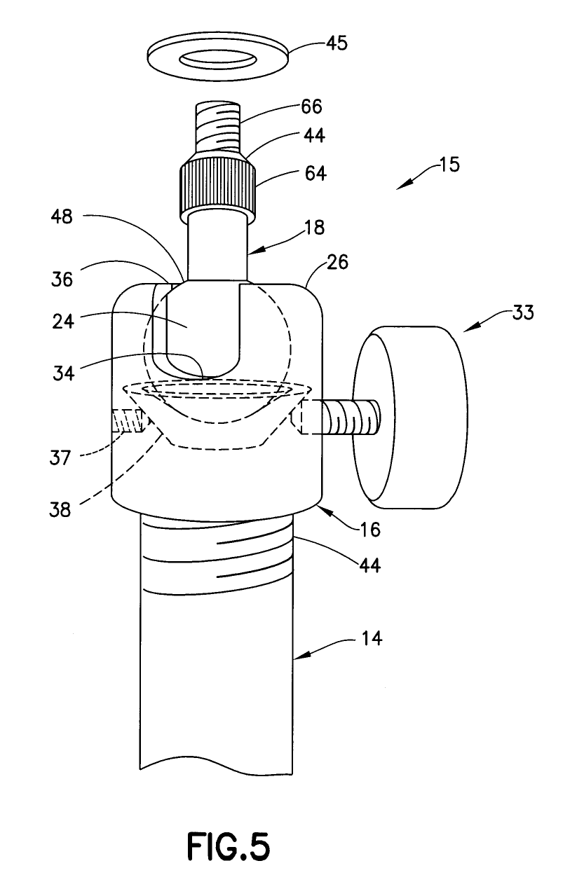

The socket 16 is defined by a substantially cylindrical body portion that includes a receiving thread in a lower portion thereof for threadedly receiving the mounting post 14. An upper portion of the socket 16 is configured to capture and retain the swivel 15. In the illustrated embodiment, a threaded knob 33 engages a threaded hole in the socket 16. A set screw 37 is positioned in the socket 16 substantially diametrically opposite the threaded hole receiving the threaded knob 33. A cup 38 is positioned in the socket 16. The cup 38, in the illustrated embodiment, has a frusto-conical shape so that as the threaded knob 33 is rotated, it pushes on the frusto-conical surface of the cup 38, which is also resting on an end of the set screw 37, causing it to move upward and engage a ball 48 forming the lower portion of the swivel 15, pushing the ball against a retaining lip (shown at 36 in FIG. 5) defined by the swivel, thereby releasably fixing the swivel's position.

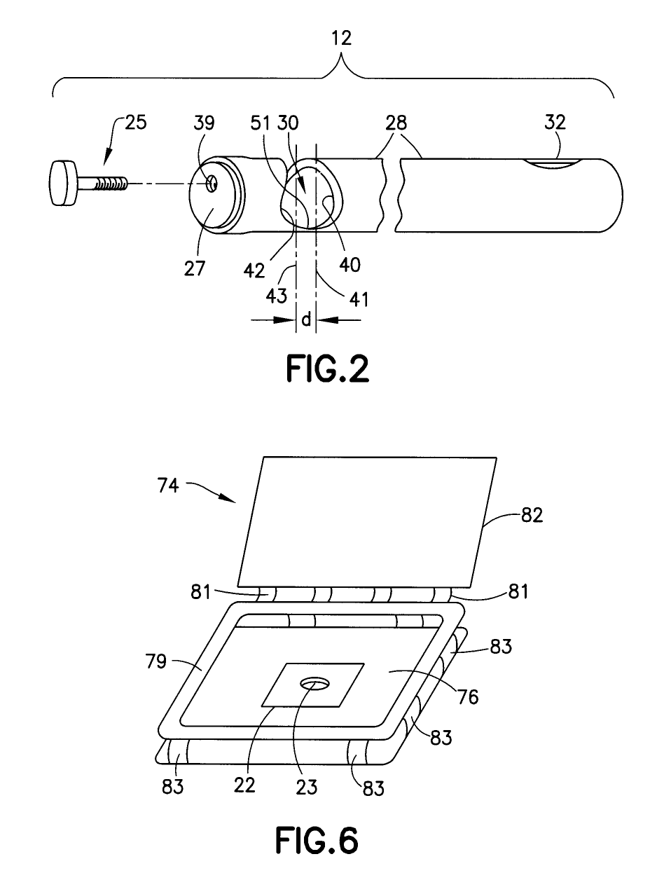

As shown in FIGS. 2-4, the slot 30 in the body portion 28 of the mounting bar 12 comprises a first radius 40 defined in part by a first centerline 41 and a second radius 42 defined in part by a second centerline 43. The first and second centerlines, 41 and 43 respectively, are separated by a distance designated by the reference letter “d.” The size of the first radius 40 and the length of the distance “d” is dependent on the size of the mounting bar 12 as well as the size of the tubing, rod, or bar that the mounting bar can be attached to. In the illustrated embodiment, the first radius 40 is tangent to a bottom surface 51 defined by the slot 30. While a second radius 42 has been described, the present invention is not limited in this regard as there can be instances where there is no second radius, but rather a substantially straight wall portion defined in part by a right angle, square corner, or other angle without is employed departing from the broader aspects of the present invention.

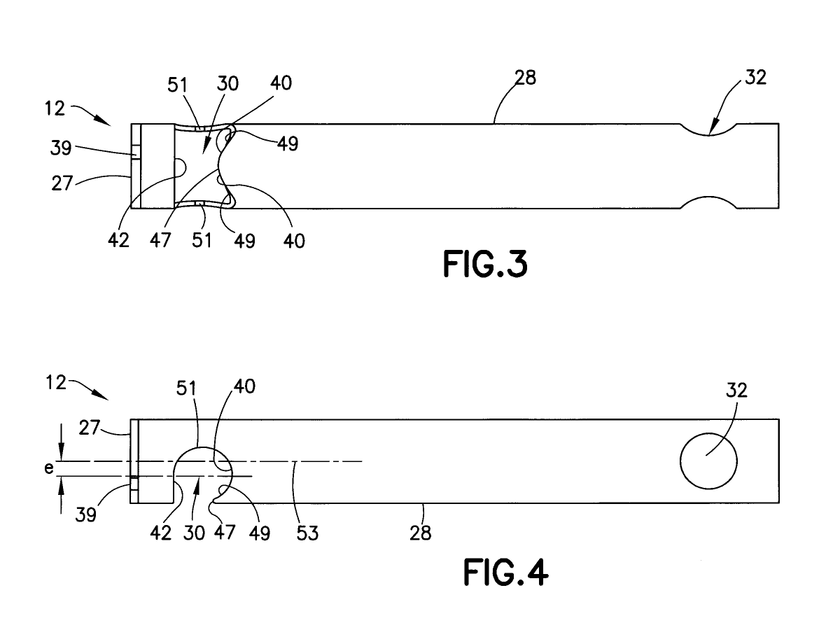

The first radius 40 is defined by a leading edge 47 and two bearing edges 49. The leading edge 47 and the two bearing edges 49 are positioned to define the slot 30 such that a center point of the slot 30 is offset from a centerline 53 by a distance “e” (FIG. 4). At least the two bearing edges 49 define elliptically enveloping surfaces that make contact with a matingly-shaped item (such as the tubing, rods, or bars of the existing support) received in the slot 30.

An end cap 27 is positioned in the body portion 28 which, in the illustrated embodiment, is hollow. The end cap 27 defines the second threaded hole 39 extending through the cap. The threaded knob 25 is threadably engageable with the second threaded hole 39 and with the tubing (or rod or bar) of the existing support to push the tubing inserted into the slot 30 against the two bearing edges 49 of the first radius 40. In pushing the tubing inserted into the slot 30 against the two bearing edges 49, the clamping force is maximized, thereby providing a secure engagement of the tubing and the slot. While the body portion 28 of the mounting bar 12 has been described as being hollow, the present invention is not limited in this regard as the body portion can also be solid. In such a case, the end cap 27 would not be needed and the second threaded hole 39 would be defined by the body portion 28.

As shown in FIG. 5, the ball 48 on the lower end of the threaded stud 18 is rotatably mounted in the body portion of the socket 16. The body portion of the socket 16 includes two slots 24 formed in an upper end thereof and extending from a top edge 26, each of the slots being located on opposite sides of the body portion and having a rounded terminal end 34. The retaining lip 36 extends at least part way around the top edge 26 between the two slots 24 and extends radially inward. The slots 24 allow the threaded stud 18 defined by the swivel to move into the slot upon rotation of the swivel, thereby providing for a tablet coupled to the swivel to be positioned at a right angle relative to the mounting bar. The ball 48 is loosely captured between the top edge 26 and the set screw 37.

The threaded stud 18 includes a ring 64 positioned about midway along the length of the stud and a bearing surface 44 on which a washer 45 is received, the washer providing a bearing surface for the receiving plate 22. Upon loosening the threaded knob 33 and turning the ring 64, the upper portion of the threaded stud 18 can be threaded into the receiving plate 22.

As shown in FIG. 6, the case 74 for holding and transporting the electronic tablet 20 comprises a bottom surface 76 in which the receiving plate 22 with the threaded aperture 23 is located and a top surface 79 coupled to the bottom surface at a suitable number of points along the edges of each of the top and bottom surfaces. The receiving plate 22 may be internal to and/or integrally formed with the bottom surface 76 or coupled thereto using any suitable means. The top surface 79 has a cut out portion through which the electronic tablet 20 can be accessed. The coupling of the bottom surface 76 to the top surface 79 may be via elastic members 83, as is shown, with the elastic members being located so as to allow the electronic tablet to be slid between the bottom surface 76 and the top surface 79. However, the present invention is not limited to the use of elastic members 83 to couple the bottom surface 76 to the top surface 79, as any suitable means of retaining the top surface 79 on the bottom surface 76 may be used. In some embodiments, the top surface 79 may be replaced in its entirety by elastic members stretching from one edge of the bottom surface 76 to an opposing edge of the bottom surface such that an electronic tablet can simply be held on the bottom surface by the elastic members. A cover or flap 82 may be coupled to either the top surface 79 or the bottom surface 76 via living hinges 81. The present invention is not limited to a cover or flap having hinges, however, as the cover may be defined by a member that slides relative to the top surface 79 to close the case 74.

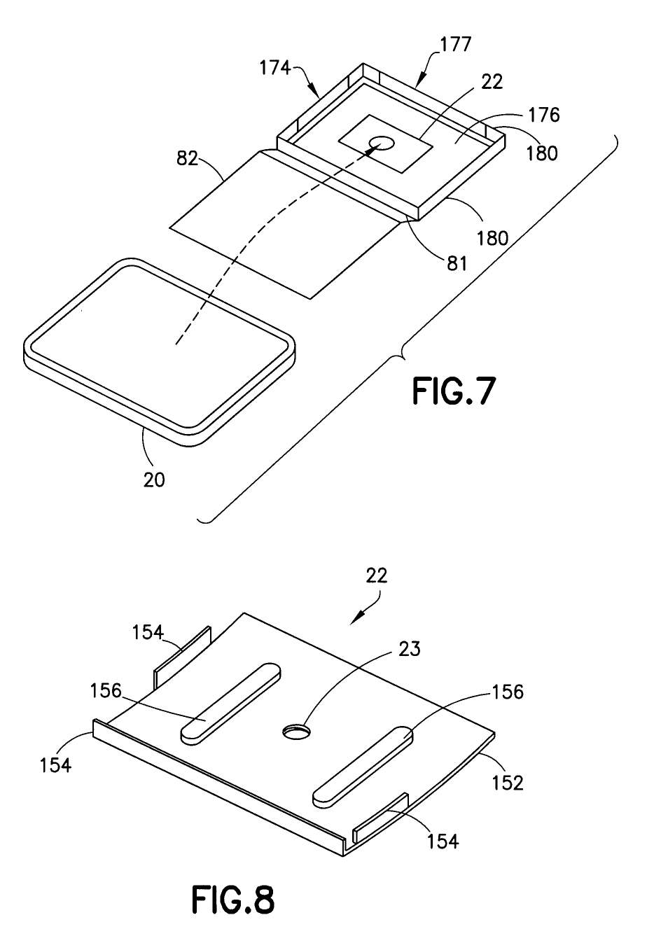

The present invention is not limited to the system 10 utilizing the case 74 to mount the electronic tablet 20. In another embodiment as shown in FIG. 7, the electronic tablet 20 may be mounted and transported in a case 174 defined by sides 180 and a bottom surface 176 in which the receiving plate 22 is mounted (e.g., using rivets or the like), stitched, or integrally formed to define a tablet retaining portion 177. Any configuration of the case 174 may have a living hinge 81 coupling a flap 82 or the like to the case, the flap being movable between an open position wherein a display screen of the electronic tablet 20 is viewable and a closed position wherein a portion of the flap covers the tablet display.

In another embodiment as shown in FIG. 8, the electronic tablet 20 may be snapplingly received directly on the receiving plate 22, the receiving plate being defined by a substantially flat member having the threaded aperture 23 extending at least partially into a lower surface 152 thereof or extending therethrough, as shown, with tabs 154 protruding substantially perpendicularly from edge portions of the lower surface 152. Each tab is sized and configured to snappingly engage a top edge portion of the electronic tablet 20. The lower surface 152 also includes raised surfaces 156, which allow the edge portions of the lower surface to be bent upward to allow the tabs 154 to snappingly engage the electronic tablet 20. The threads 66 on the stud 18 are threadedly receivable in the threaded aperture 23.

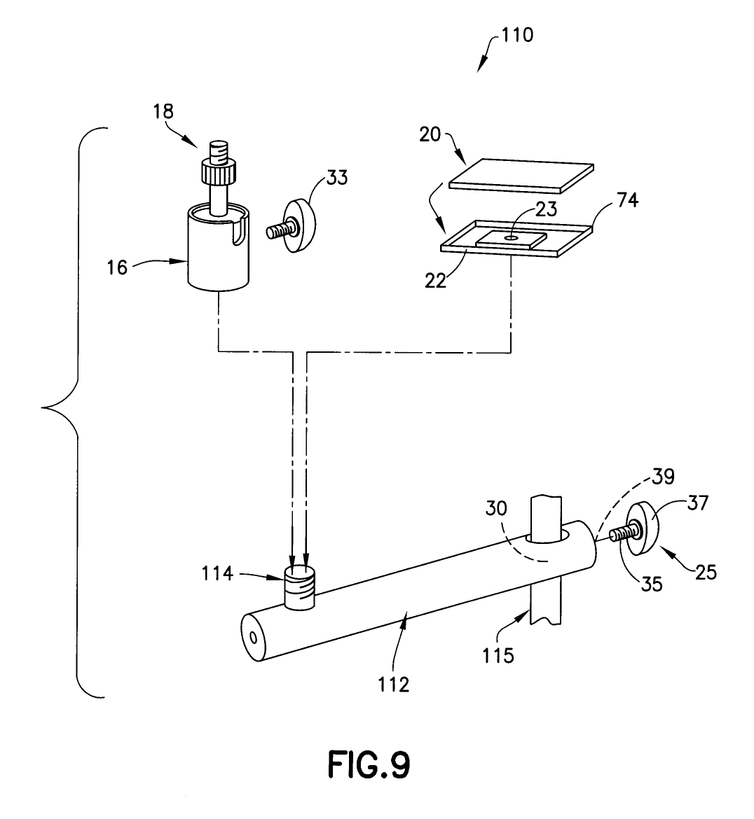

As shown in FIG. 9, an alternate embodiment of the system is designated generally by the reference number 110 and is hereinafter referred to as “system 110.” System 110 is similar to system 10 as described above, but system 110 comprises a mounting bar 112 having a lug 114 protruding therefrom. The lug 114 is integrally formed with the mounting bar 112, for example, by being welded thereon. An end of the lug 114 is threaded. Accordingly, any element suitably configured with receiving threads, including but not limited to, the socket 16 and the receiving plate 22, can be coupled to the lug 114. In this system 110, the slot 30 may be utilized to attach the mounting bar 112 to an existing support 115 such as a microphone stand or the like. A clamping mechanism 25 may be utilized to secure the mounting bar 112 to the existing support 115.

Although this invention has been shown and described with respect to the detailed embodiments thereof, it will be understood by those of skill in the art that various changes may be made and equivalents may be substituted for elements thereof without departing from the scope of the invention. In addition, modifications may be made to adapt a particular situation or material to the teachings of the invention without departing from the essential scope thereof. Therefore, it is intended that the invention not be limited to the particular embodiments disclosed in the above detailed description, but that the invention will include all embodiments falling within the scope of the foregoing description.

What is claimed is:

1. A case for holding and transporting an electronic tablet, the case comprising:
a bottom defined by a surface;
a top defining a surface having a cut out portion through which the electronic tablet can be accessed, the surface defining the top being coupled to the surface defining the bottom by a plurality of members located along the edges of the surfaces defining the top and the bottom;
a cover coupled to the top portion and movable between an open position wherein the electronic tablet is viewable and a closed position wherein a portion of the cover covers the electronic tablet; and
a receiving plate located at the surface defining the bottom;
wherein the receiving plate is configured to be coupled to a system for mounting the electronic tablet.

2. The case of claim 1, wherein the receiving plate is configured to threadedly receive the system for mounting the electronic tablet.

3. The case of claim 1, wherein the receiving plate is fastened to the surface defining the bottom.

4. The case of claim 1, wherein the receiving plate is at least one of internal to and integral with the surface defining the bottom.

5. A system for mounting an electronic tablet, the system comprising:
a mounting bar configured to be coupled to a support;
a mounting post coupled to the mounting bar;
a socket located on the mounting post;
an attachment mechanism cooperably associated with the socket; and
a receiving plate coupled to the attachment mechanism;
wherein the electronic tablet is configured to be coupled to the receiving plate.

6. The system of claim 5, wherein the mounting bar comprises,
a mounting slot located in a body portion of the mounting bar, the mounting slot being defined by a first radius extending through the body portion, a bottom surface substantially tangent to the first radius, the bottom surface extending toward an end of the body portion, and a second radius extending from the bottom surface to an outside surface of the body portion; and
a clamping mechanism received in the end of the body portion proximate the mounting slot;
wherein the clamping mechanism is operable to engage a tubing member positioned in the mounting slot, thereby urging the tubing member against the first radius to releasably retain the mounting bar on the tubing member.

7. The system of claim 6, wherein the mounting bar further comprises,
a through hole located proximate the second end of the body portion, and
a second clamping mechanism received in an end of the body portion proximate the through hole.

8. The system of claim 5, wherein the socket is coupled to an upper end of the mounting post.

9. The system of claim 8, wherein the socket is non-rotatably coupled to the upper end of the mounting post.

10. The system of claim 8, wherein the attachment mechanism comprises,
a ball retained in the socket,
a stud extending from the ball such that the receiving plate can be coupled to the stud, and
a third clamping mechanism received in the socket and configured to clamp the ball in the socket.

11. The system of claim 10, wherein the stud comprises an upper portion threadedly receivable in the receiving plate.

12. The system of claim 10, wherein the stud comprises a ring located therearound, the ring being configured to facilitate the turning of the stud to couple the receiving plate thereto.

13. The system of claim 5, further comprising a sleeve in which the electronic tablet is mounted, the sleeve being coupled to the receiving plate.

14. The system of claim 5, wherein the mounting post is integrally coupled to the mounting bar.

15. A kit for mounting an electronic tablet to a support, the kit comprising:
a mounting bar configured to be coupled to the support;
a mounting post; and
a socket having an attachment mechanism cooperably associated therewith;
wherein the electronic tablet is configured to be coupled to the attachment mechanism.

16. The kit of claim 15, wherein the mounting bar comprises,
a mounting slot located in a body portion of the mounting bar, the mounting slot being defined by a first radius extending through the body portion, a bottom surface substantially tangent to the first radius, the bottom surface extending toward an end of the body portion, and a second radius extending from the bottom surface to an outside surface of the body portion; and
a first clamping mechanism received in the end of the body portion proximate the mounting slot;
wherein upon engagement of the clamping mechanism and a tubing member positioned in the mounting slot, the tubing member positioned in the mounting slot is pushed against the first radius.

17. The kit of claim 16, wherein the mounting bar further comprises,
a through hole located proximate the second end of the body portion, and
a second clamping mechanism located in the second end proximate the through hole.

18. The kit of claim 15, further comprising a receiving plate on which the electronic tablet is mounted, and wherein the receiving plate is mountable to the attachment mechanism.

19. The kit of claim 18, wherein the attachment mechanism cooperably associated with the socket comprises,
a ball located in the socket, and
a stud coupled to the ball,
wherein the receiving plate is mountable to the stud.

20. The kit of claim 19, wherein the stud comprises an upper portion rotatably connected to a lower portion, the receiving plate being mountable to the stud at the upper portion, and the lower portion being fixed to the ball.

21. The kit of claim 15, further comprising a sleeve in which the electronic tablet is mountable, the sleeve being configured to be coupled to the attachment mechanism.
